(19) United States
(12) Patent Application Publication
(10) Pub. No.: US 2003/0109125 A1
(43) Pub. Date: Jun. 12, 2003

(54) Fuse structure for a semiconductor device and manufacturing method thereof

(76) Inventor: Chewnpu Jou, Hsinchu Hsien (TW)

Correspondence Address: J.C. Patents, Inc., Suite 250, 4 Venture, Irvine, CA, 92618, US

(21) Appl. No.: 10/013,904

(22) Filed: Dec. 10, 2001

(51) Int. Cl. H01L 21/44

(52) U.S. Cl. 438/601

(57) ABSTRACT

A fuse structure in a semiconductor device and a manufacturing method thereof. The fuse structure includes a insulation layer, a metal layer on a top surface of the first insulation layer, the metal layer having a middle portion narrower than a first and a second outer portions of the metal layer, a second insulation layer over the metal layer, a first top metal layer and a second top metal layer on a top surface of the second insulation layer and a plurality of vias connecting the first and second top metal layers with the metal layer respectively. The first top metal layer is connected to the first outer portion of the metal layer and the second top metal layer is connected to the second outer portion of the metal layer. The middle portion is disposed between the first and second outer portions of the metal layer.

### FIELD OF THE INVENTION

The present invention relates to a fuse structure for a semiconductor device and a manufacturing method thereof. More particularly, the invention relates to a closed fuse structure in a semiconductor device and a fabricating method thereof.

### BACKGROUND OF INVENTION

As semiconductor devices continue to decrease in size they become more susceptible to imperfections or impurities in the silicon crystal. The failure of a single diode or transistor in a chip can render it defective. In order to address this problem semiconductor devices are increasingly making use of redundant circuits with connecting fuses. If a circuit is found to be defective after manufacture a fuse can be electrically altered disabling it and possibly enabling a redundant circuit. In the case of memory devices, defective memory cells can have their address reassigned to that of a good memory cell. An alternative reason for using fuses in integrated circuits is to program control words such as identification codes into a chip permanently.

Kawanabe et al. in U.S. Pat. No. 4,795,720 discloses a METHOD FOR PRODUCING SEMICONDUCTOR DEVICES AND CUTTING FUSES. This method uses a laser beam to sever normally closed fuses. An opening in the outer protective layer allows a laser beam to sever a fuse. However the opening in the protective covering can allow contamination in during processing, the hole must be covered with a protective layer after the severance occurs. Often when the fuse is severed debris is created thereby possibly rendering nearby MOS structures inoperative.

In U.S. Pat. No. 4,536,948 Te Velde et al. entitled METHOD OF MANUFACTURING PROGRAMMABLE SEMICONDUCTOR DEVICE, discloses a method of blowing fuses. Often the fuses are formed with polycrystalline silicon or metal access lines. For a polycrystalline silicon fuse a high voltage (e.g. 15-20 v) needs to be applied which heats and oxidizes the fuse into insulating SiO₂. ICs are normally covered with a protective passivating layer of Si₃N₄, SiO₂, or sandwich of Si₃N₄/SiO₂. However the heat from burning the polycrystalline silicon or metal fuse is also likely to fracture the overlying passivating layer. Therefore, polycrystalline silicon fuses often require an opening in the overhead layer, which can allow in environmental moisture that can corrode conductors or electrical contacts in the device. A second disadvantage of this type of technique is that fuse material may splatter as it blows, landing on the surface of the device, possibly damaging the device. A further drawback is that the fuse programming power requires relatively large access (addressing) transistors, which increases the size and cost of the IC.

Therefore a need remains for a normally closed fuse that can be blown with a relatively low voltage, and will not damage surrounding structures.

### SUMMARY OF THE INVENTION

These and other features, which characterize the invention, are set forth in the claims annexed hereto and forming a further part hereof. However, for a better understanding of the invention, and of the advantages and objectives attained through its use, reference should be made to the drawings, and to the accompanying descriptive matter, in which there is described exemplary embodiments of the invention.

It is therefore one object of the invention to provide a fuse structure within a semiconductor device and a method of forming thereof.

It is another object of the invention to provide a fuse structure that can be blown with a relatively low voltage/current.

It is yet another object of the invention to provide a fuse structure that when blow will not adversely affect surrounding semiconductor structures.

Accordingly, the invention provides a fuse structure in a semiconductor device, comprising a insulation layer; a metal layer on a top surface of the first insulation layer, the metal layer having a middle portion narrower than a first and a second outer portions of the metal layer; a second insulation layer over the metal layer; a first top metal layer and a second top metal layer on a top surface of the second insulation layer; and a plurality of vias connecting the first and second top metal layers with the metal layer respectively, wherein the first top metal layer is connected to the first outer portion of the metal layer and the second top metal layer is connected to the second outer portion of the metal layer, wherein the middle portion is disposed between the first and second outer portions of the metal layer.

In the above-mentioned fuse structure, the metal layer has higher resistivity than the first and second top metal layer.

Accordingly, the invention provides a fuse structure in a semiconductor device, comprising: a first metal layer; a first insulation layer on the first metal layer;

a second metal layer on a top surface of the first insulation layer, the second metal layer having a middle portion narrower than a first and a second outer portions of the second metal layer; a second insulation layer over the second metal layer; a first top metal layer and a second top metal layer on a top surface of the second insulation layer; and a plurality of vias connecting the first and second top metal layers with the second metal layer respectively, wherein the first top metal layer is connected to the first outer portion of the second metal layer and the second top metal layer is connected to the second outer portion of the second metal layer, wherein the middle portion is disposed between the first and second outer portions of the second metal layer.

In the above-mentioned fuse structure, the second metal layer has higher resistivity than the first and second top metal layers.

In the above-mentioned fuse structure, the first metal layer, the first insulation layer and the second metal layer are combined to be a metal insulator metal (MIM) capacitor.

Accordingly, the invention provides a manufacturing method for a fuse structure in a semiconductor device, comprising forming a insulation layer; forming a metal layer on a top surface of the first insulation layer, the metal layer having a middle portion narrower than a first and a second outer portions of the metal layer; forming a second insulation layer over the metal layer; forming a first top metal layer and a second top metal layer on a top surface of the second insulation layer; and forming a plurality of vias connecting the first and second top metal layers with the metal layer respectively, wherein the first top metal layer is connected to the first outer portion of the metal layer and the second top metal layer is connected to the second outer portion of the metal layer, wherein the middle portion is disposed between the first and second outer portions of the metal layer.

In the above-mentioned manufacturing method for a fuse structure, the metal layer has higher resistivity than the first and second top metal layers.

In the above-mentioned manufacturing method for a fuse structure, the first insulating layer includes a oxide layer of Ta₂O_{5.}

In the above-mentioned manufacturing method for a fuse structure, the metal layer comprises a TiN film.

Accordingly, the invention provides a manufacturing method of a fuse structure in a semiconductor device, comprising: forming a first metal layer; forming a first insulation layer on the first metal layer; forming a second metal layer on a top surface of the first insulation layer, the second metal layer having a middle portion narrower than a first and a second outer portions of the second metal layer; forming a second insulation layer over the second metal layer; forming a first top metal layer and a second top metal layer on a top surface of the second insulation layer; and forming a plurality of vias connecting the first and second top metal layers with the second metal layer respectively, wherein the first top metal layer is connected to the first outer portion of the second metal layer and the second top metal layer is connected to the second outer portion of the second metal layer, wherein the middle portion is disposed between the first and second outer portions of the second metal layer.

In the above-mentioned manufacturing method for a fuse structure, the second metal layer has higher resistivity than the first and second top metal layers.

In the above-mentioned manufacturing method for a fuse structure, the first metal layer, the first insulation layer and the second metal layer are combined to be a metal insulator metal (MIM) capacitor.

### BRIEF DESCRIPTION OF DRAWINGS

FIG. 1 shows the fuse structure of a preferred embodiment of the invention;

FIG. 2 shows a top view of the upper metallic layer;

FIG. 3 shows the via connections; and

FIG. 4 shows a preferred implementation of the invention.

### DETAILED DESCRIPTION

In the following detailed description of the preferred embodiments, reference is made to the accompanying drawings which form a part hereof, and in which is shown by way of illustration specific preferred embodiments in which the invention may be practiced. The preferred embodiments are described in sufficient detail to enable these skilled in the art to practice the invention, and it is to be understood that other embodiments may be utilized and that logical, changes may be made without departing from the spirit and scope of the present invention. The following detailed description is, therefore, not to be taken in a limiting sense, and the scope of the present invention is defined only be the appended claims.

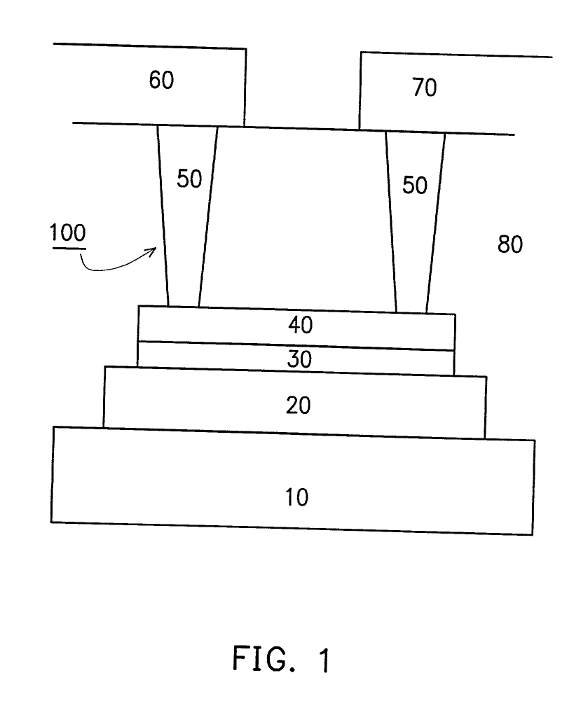

The method in which to form the fuse structure as shown in a cross-sectional view in FIG. 1 is described. In the semiconductor device, a bottom metal layer 20 is typically formed on a insulation layer, such as a dielectric layer 10. The bottom metal layer 20 is formed by, for example, a chemical vapor deposition (CVD) process to evenly deposit a metal layer on the surface of the dielectric layer 10. Once the pattern of the bottom metal layer 20 is established, an etching process removes excess portions of the bottom metal layer and the bottom metal layer 20 is formed thereafter. An insulation layer 30 is then formed. In a preferred embodiment, the insulation layer 30 comprises a thick oxide layer such as Ta₂O₅, or a combination of oxide layers and spin-on-glass. An upper metallic layer 40 is then formed on the insulation layer 30. In a preferred embodiment the upper metallic layer 40 is a TiN film, formed in thickness of 200-500 Å by means of a chemical vapor deposition (CVD) method under conditions that TiCl₄ is used as raw materials, NH₃ gas is used as a reactive gas, the temperature within the reactive furnace is maintained at 300-500 degrees Celsius and the pressure within the reactive furnace is maintained at 0.1-2 Torr. The bottom metal layer 20, the insulation layer 30 and the upper metallic layer 40 can be a metal-insulator-metal (MIM) capacitor, which is compatible with a RF-CMOS semiconductor process.

The upper metallic layer 40 have typically poor conductivity characteristics, or in other words, high resistivity. In a preferred embodiment of the invention, the resistivity is roughly 10 Ω per square inch with an upper metallic layer 40 having a thickness of 0.1 um. The resistivity of the upper metallic layer 40 can be varied by altering the material of the upper metallic layer for more or less resistivity, or by changing the length, width, or thickness of the upper metallic layer. As shown in FIG. 2 in a preferred embodiment the upper metallic layer 40 is formed with a shape having a narrow middle portion 42 in contrast with wider outer portions. Therefore, by providing a narrow channel between the two via contacts, an area of high resistivity is provided necessitating less current and a stable burning location in the upper metallic layer 40.

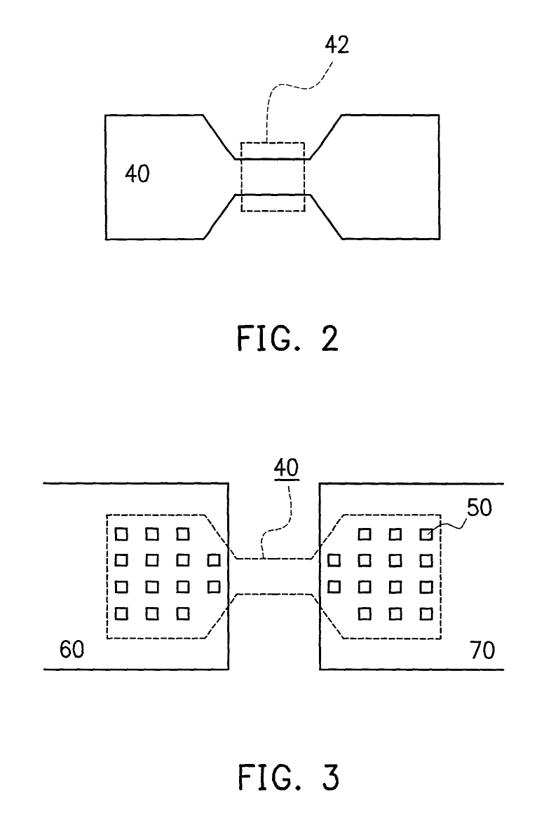

An inter-metal dielectric layer 80 covers the fuse structure 100, and a chemical mechanical polishing (CMP) process is used to planarize the surface of the inter-metal dielectric layer 80. A photoresist layer (not shown), and lithographic process is used to define the position of the vias 50. The number and size of vias can vary depending on current considerations, and the upper metallic layer 40. One embodiment of the via structure is shown in a top view of the structure in FIG. 3, vias 50 are used connecting the upper metal layers 60 and 70 with the upper metallic layer 40. The inter-metal dielectric layer portion 80 not covered by the photoresist is removed, and then the photoresist layer is removed. A sputtering process is performed to form a metal layer that fills the via holes. A etching back process is then performed to remove excess metal so the surface of the metal layer in the via holes is aligned with the surface of the inter-metal dielectric layer so as to form the via plugs 50. A top metal layer is then deposited on the surface of the dielectric layer and the vias, and an etching process is used to form the individual metal layers 60 and 70.

When a fuse is to be broken or burned, a high current is passed through the top metal layers 60 and 70, through a via 50 into the upper metallic layer 40. The high resistivity in the narrow portion of the upper metallic layer 40 will cause a break to occur severing the electrical connection between the upper metal layers 60 and 70. However the design implementation of the upper metallic layer as previously described can ensure that only a relatively small current/voltage is required to blow the fuse.

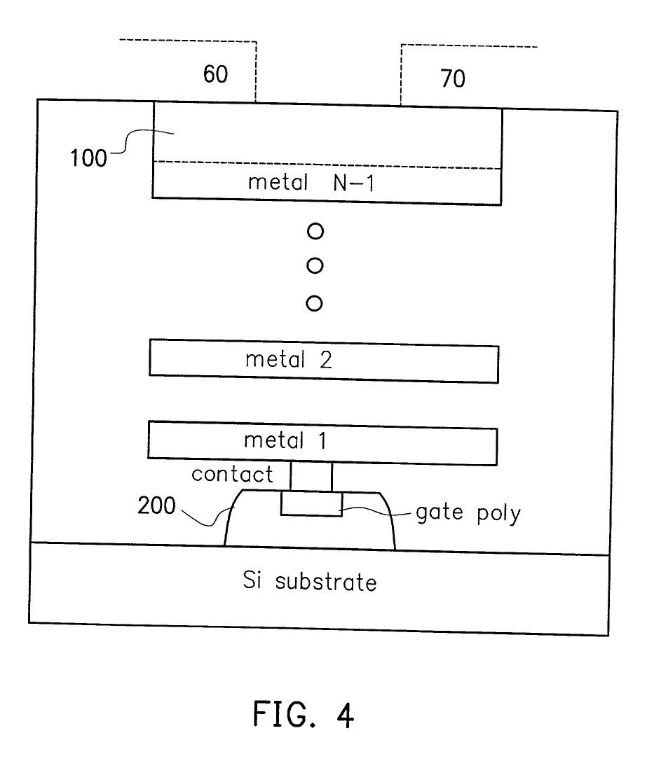

FIG. 4 shows a preferred implementation of the fuse structure 100 in a semiconductor device. Structures 200 on developed on a Si substrate. Overlapping metal lines are then formed above the structures 200 such as word lines. The fuse structure is placed on an uppermost metal layer (Metal n-1) so as to be accessible from the top metal layers 60 and 70. This design has the advantage that the residue of melt metal will stay near the upper metallic layer 40 which can be placed a fair distance from any MOS transistors therefore not interfering with the MOS transistors performance. The embodiment is also compatible with a MOS connecting to many metal-insulator-metal (MIM) capacitors. This will cause less reliability problems generated by the melted fuse residues.

Various additional modifications may be made to the illustrated embodiments without departing from the spirit and scope of the invention. Therefore, the invention lies in the claims hereinafter appended.

What is claimed:

1. A fuse structure in a semiconductor device, comprising:
a insulation layer;
a metal layer on a top surface of the first insulation layer, the metal layer having a middle portion narrower than a first and a second outer portions of the metal layer;
a second insulation layer over the metal layer;
a first top metal layer and a second top metal layer on a top surface of the second insulation layer; and
a plurality of vias connecting the first and second top metal layers with the metal layer respectively, wherein the first top metal layer is connected to the first outer portion of the metal layer and the second top metal layer is connected to the second outer portion of the metal layer, wherein the middle portion is disposed between the first and second outer portions of the metal layer.

2. The fuse structure of claim 1, wherein the metal layer has higher resistivity than the first and second top metal layers.

3. A fuse structure in a semiconductor device, comprising:
a first metal layer;
a first insulation layer on the first metal layer;
a second metal layer on a top surface of the first insulation layer, the second metal layer having a middle portion narrower than a first and a second outer portions of the second metal layer;
a second insulation layer over the second metal layer;
a first top metal layer and a second top metal layer on a top surface of the second insulation layer; and
a plurality of vias connecting the first and second top metal layers with the second metal layer respectively, wherein the first top metal layer is connected to the first outer portion of the second metal layer and the second top metal layer is connected to the second outer portion of the second metal layer, wherein the middle portion is disposed between the first and second outer portions of the second metal layer.

4. The fuse structure of claim 3, wherein the second metal layer has higher resistivity than the first and second outer portions of the metal layer.

5. The fuse structure of claim 3, wherein the first metal layer, the first insulation layer and the second metal layer are combined to be a metal insulator metal (MIM) capacitor.

6. A manufacturing method for a fuse structure in a semiconductor device, comprising:
forming a insulation layer;
forming a metal layer on a top surface of the first insulation layer, the metal layer having a middle portion narrower than a first and a second outer portions of the metal layer;
forming a second insulation layer over the metal layer;
forming a first top metal layer and a second top metal layer on a top surface of the second insulation layer; and
forming a plurality of vias connecting the first and second top metal layers with the metal layer respectively, wherein the first top metal layer is connected to the first outer portion of the metal layer and the second top metal layer is connected to the second outer portion of the metal layer, wherein the middle portion is disposed between the first and second outer portions of the metal layer.

7. The manufacturing method of claim 6, wherein the metal layer has higher resistivity than the first and second top metal layer.

8. The manufacturing method of claim 6, wherein the first insulating layer includes a oxide layer of Ta₂O₅

9. The manufacturing method of claim 6, wherein the metallic layer comprises a TiN film.

10. A manufacturing method of a fuse structure in a semiconductor device, comprising:
forming a first metal layer;
forming a first insulation layer on the first metal layer;
forming a second metal layer on a top surface of the first insulation layer, the second metal layer having a middle portion narrower than a first and a second outer portions of the second metal layer;
forming a second insulation layer over the second metal layer;
forming a first top metal layer and a second top metal layer on a top surface of the second insulation layer; and
forming a plurality of vias connecting the first and second top metal layers with the second metal layer respectively, wherein the first top metal layer is connected to the first outer portion of the second metal layer and the second top metal layer is connected to the second outer portion of the second metal layer, wherein the middle portion is disposed between the first and second outer portions of the second metal layer.

11. The manufacturing method of claim 10, wherein the second metal layer has higher resistivity than the first and second top metal layers.

12. The manufacturing method of claim 10, wherein the first insulating layer includes a oxide layer of Ta₂O_{5.}

13. The manufacturing method of claim 10, wherein the metallic layer comprises a TiN film.

14. The fuse structure of claim 10, wherein the first metal layer, the first insulation layer and the second metal layer are combined to be a metal insulator metal (MIM) capacitor.

15. The manufacturing method of claim 10, wherein the first insulating layer is including a oxide layer of Ta₂O_{5.}

16. The manufacturing method of claim 10, wherein the second metal layer comprises a TiN film.
